(19) United States
(12) Patent Application Publication
(10) Pub. No.: US 2020/0309845 A1
(43) Pub. Date: Oct. 1, 2020

(54) OPTIMIZATION METHOD FOR INTEGRATED CIRCUIT WAFER TEST

(71) Applicant: SINO IC TECHNOLOGY CO., LTD., Shanghai (CN)

(72) Inventors: Hua Wang, Shanghai (CN); Zhiyong Zhang, Shanghai (CN); Jianbo Ling, Shanghai (CN); Jianhua Qi, Shanghai (CN); Yuanhua Liu, Shanghai (CN); Haiying Ji, Shanghai (CN)

(21) Appl. No.: 16/759,350

(22) PCT Filed: Apr. 2, 2018
(86) PCT No.: PCT/CN2018/081529

§ 371 Date: Apr. 26, 2020

(30) Foreign Application Priority Data
Mar. 28, 2018 (CN) 201810264068.9

(51) Int. Cl. G01R 31/28

(52) U.S. Cl. CPC G01R 31/2834; G01R 31/2891

(57) ABSTRACT

The present invention relates to an optimization method for an integrated circuit wafer test, which is applied in an integrated circuit wafer test process. By means of pre-specifying and storing coordinates of a die to be tested on a wafer in a test system, then testing the pre-specified die according to a design map by means of a test process, and adjusting in real time a range of pre-specified coordinates according to a test result of a current die, a desired test coordinate map is finally obtained so as to cover the maximum number of fail dies in an optimized solution, thereby reducing test time, improving testing efficiency, reducing the frequency of testing hardware usage and increasing service life. By means of calculating a suitable coverage number in the present invention, a smaller number of fail chips that reach a package will also be obtained without increasing the cost of the package. At the same time, the number of probe card tests is reduced, and the hardware service life is increased.

### TECHNICAL FIELD

The disclosure herein relates to the field of a test and inspection technology, in particular to an optimization method for an integrated circuit wafer test.

### BACKGROUND

ATE (Automatic Test Equipment): an automatic testing machine for semiconductor integrated circuits (IC), used to check the integrity of the functions of integrated circuits. Wafer: wafer refers to a silicon wafer used in the manufacture of silicon semiconductor integrated circuits, because its shape is circular, it is called a wafer. Die: an independent integrated circuit chip on the wafer.

Due to the advancement of integrated circuit design and manufacturing technology, the chip size is getting smaller and smaller, but the silicon wafer size has been increased from 200 mm to 300 mm. There are 100,000 chips, and due to the large number of integrated circuit test parameters and long test time, it is usually necessary to test a large number of integrated circuit wafers for all dies, which requires a large amount of test time, which increases the test cost accordingly.

Secondly, the probe card used for wafer testing has a certain service life. When the probe card contacts the die on the wafer once, there will be a certain loss, and after a certain number of times, it will affect the test results and cannot be used. The cost of designing and manufacturing test probe cards is also quite expensive. In the face of the testing needs of a large number of wafers, frequent production of probe cards also increases the cost of hardware expenditure.

### SUMMARY

The present invention proposes an optimization method for an integrated circuit wafer test to solve the problem of low wafer test efficiency. The method is used in integrated circuit wafer testing, pre-specifying the die coordinates to be tested and storing them in the test system, testing the specified die during the test and adjusting in real time according to test results, finally getting the required test coordinate graphic reference to the generated test, thereby reducing test time, improving testing efficiency, reducing the frequency of testing hardware usage and increasing service life.

The technical solution of the present invention is: an optimization method for an integrated circuit wafer test, it includes the following steps:

1) pre-designing a number of dies and coordinates of a die for a wafer to be tested by means of the size of the wafer, the number of dies and the number of test stations that the probe card can test;

2) storing the coordinates of a die to be tested in a coordinate library to be tested, storing the other coordinates in a coordinate library not to be tested and designing the walking sequence of the wafer test;

3) obtaining the coordinates of a die to be tested from the coordinate library to be tested by a test system, starting the test, controlling the wafer prober to test at a specified coordinates by the control system, by means of the coordinates sent by the test system;

4) the test result is returned to the test system and the test result is judged by the test system:
1) if the test result is qualified, then put the coordinates of the die into a coordinate library that has completed the test;
2) if the test result is failed, then put the coordinates of the die into a coordinate library that has completed the test, the test system generates 8 die coordinates around the center of the coordinates of the die, and compare the 8 generated die coordinates with the coordinate library that has completed the test one by one, if the generated die coordinates already exist in the coordinate library that has completed, then remove the generated die coordinates; if the generated die coordinates not exist in the coordinate library that has completed, then add the generated die coordinates into the coordinate library to be tested;

5) continue to return to step 3) for the next coordinate die test until the coordinate library to be tested is tested;

6) processing all the coordinates testing result in the coordinate library not to be tested as being qualified;

7) merging the coordinate library that has completed the test and the coordinate library not to be tested, if the coordinates exist in the two libraries at the same time, the coordinate library that has completed the test is taken as the final result, and combining coordinate libraries to generate actual test graphics for subsequent processes.

The specific step of pre-designing the test graphics in step 1) includes the following steps: designing the test graphics by means of the overall chip yield and the test efficiency to be achieved, firstly pre-setting the coordinates, and the edge of the wafer is the area that must be tested, take 1 or 2 die on the edge as a unit, setting one circle of the edge of the wafer as the test coordinate; secondly setting the middle position as required, designing the test position module and spacing value according to the product yield of the product and the required test efficiency, setting the coordinates of the whole wafer according to the test coordinates; finally combine test coordinates as design test graphics.

The beneficial effects of the present invention are: the optimization method for an integrated circuit wafer test, for products with more mature technology and higher wafer yield, the method of the present invention can significantly improve test efficiency and reduce test time. Through proper calculation of the number of coverage, less FAIL chips will flow to the package without increasing the cost of the package. At the same time, the number of times the needle card is lowered is reduced, and the hardware life is increased.

### BRIEF DESCRIPTION OF FIGURES

FIG. 1 is a schematic diagram of an optimization method for an integrated circuit wafer test of the present invention.

FIG. 2 is a diagram of the coordinate position of the chip surrounding the die to be tested according to the present invention.

FIG. 3 is a schematic diagram of taking two preset coordinates on the edge of a wafer according to the present invention.

FIG. 4 is a schematic diagram of taking preset pre-set coordinates in the middle of a wafer according to the present invention.

FIG. 5 is a schematic diagram of preset coordinates of the present invention.

FIG. 6 is a test graphic of an actual wafer after the algorithm is adopted by the present invention.

### DETAILED DESCRIPTION

Different types of chips and different manufacturing processes result in a huge difference in wafer yield. It may be 99% for product A, 70% for product B, and 20% to 30% for product C. But the test need to test all die of the whole wafer. For product A, 1% of defective products need to be picked, but the test time of the whole piece needs to be paid, and the test efficiency and cost ratio are poor.

From the statistics of a large number of wafer test results, there is a large correlation between the failure of adjacent die, that is, if the die with (X=100, Y=100) coordinates is in a failed state, with the die as the center, There is a high probability of failure of the 8 die around it.

By pre-specifying the die coordinates to be tested and storing them in the test system, testing the specified die during the test and adjusting in real time according to test results, finally getting the required test coordinate graphic reference to the generated test, thereby reducing test time, improving testing efficiency, reducing the frequency of testing hardware usage and increasing service life.

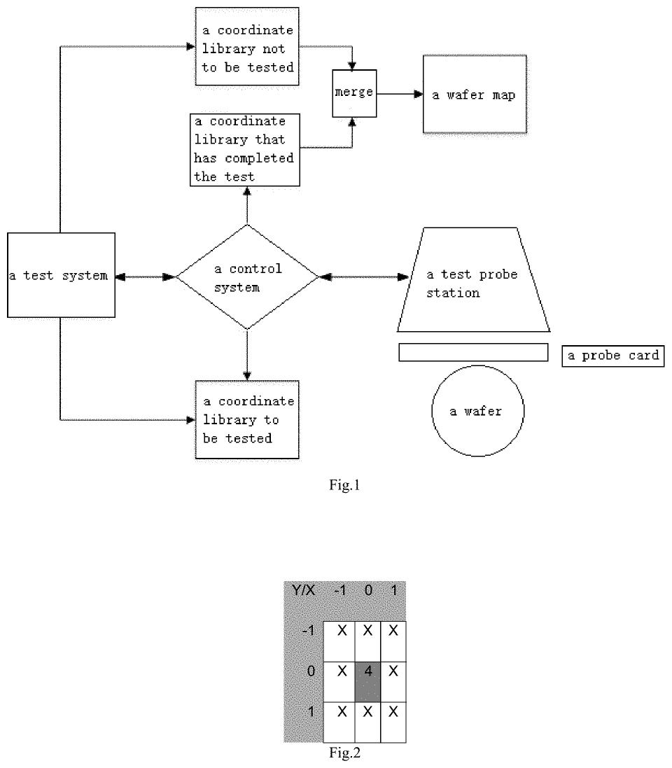

FIG. 1 is a schematic diagram of an optimization method for an integrated circuit wafer test of the present invention, following the steps below:

1. pre-designing a number of dies and coordinates of a die for a wafer to be tested by means of the size of the wafer, the number of dies and the number of test stations that the probe card can test;

2. storing the coordinates of a die to be tested in a coordinate library to be tested, storing the other coordinates in a coordinate library not to be tested and designing the walking sequence of the wafer test;

3. obtaining the coordinates of a die to be tested from the coordinate library to be tested by a test system, starting the test, controlling the wafer prober to test at a specified coordinates by the control system, by means of the coordinates sent by the test system;

4. the test result is returned to the test system and the test result is judged by the test system, (1) if the test result is qualified, then put the coordinates of the die into a coordinate library that has completed the test; (2) if the test result is failed, then put the coordinates of the die into a coordinate library that has completed the test, the test system generates 8 die coordinates around the center of the coordinates of the die, mark the position of the chip coordinates around the die to be tested and failed die 4 as shown in FIG. 2, and compare the 8 generated die coordinates with the coordinate library that has completed the test one by one, if the generated die coordinates already exist in the coordinate library that has completed, then remove the generated die coordinates; if the generated die coordinates not exist in the coordinate library that has completed, then add the generated die coordinates into the coordinate library to be tested;

5. continue to return to step 3) for the next coordinate die test until the coordinate library to be tested is tested;

6. processing all the coordinates testing result in the coordinate library not to be tested as being qualified;

7. merging the coordinate library that has completed the test and the coordinate library not to be tested, if the coordinates exist in the two libraries at the same time, the coordinate library that has completed the test is taken as the final result, and combining coordinate libraries to generate actual test graphics for subsequent processes.

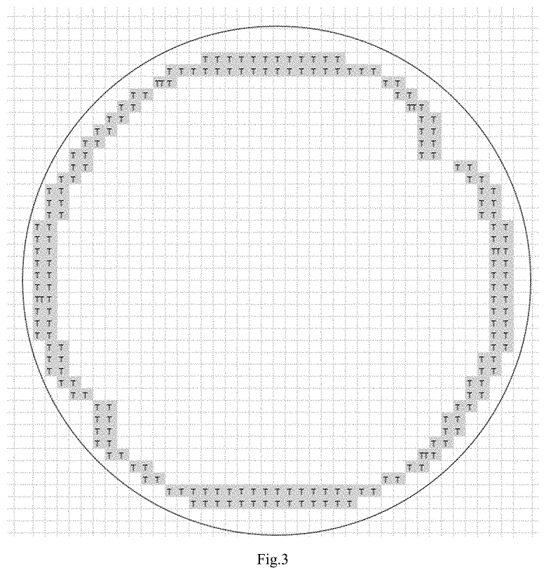

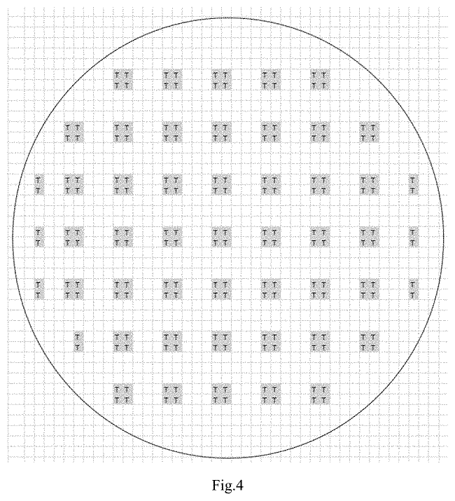

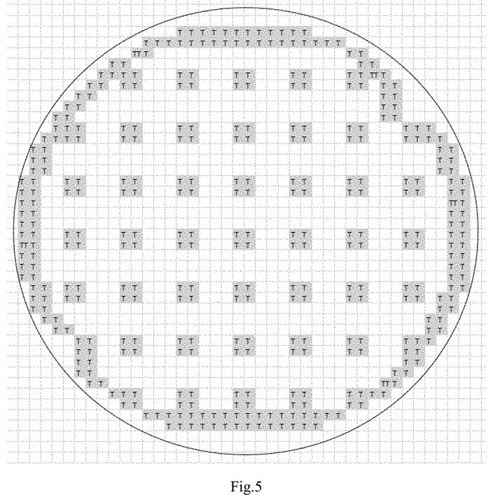

Firstly pre-setting the coordinates in step 1, the test graphics can be set flexibly. Normally, it should be designed according to the previous piece yield and the test efficiency to be achieved. Normally, the edge of the wafer is prone to failure due to processes and cutting, and this part of the area must be tested (taking 1 or 2 on the edge), secondly setting the middle position according to the requirements. The module and the spacing value are designed according to the product yield of the product itself. Taking the schematic diagram of two preset coordinates at the edge of the wafer as shown in FIG. 3, and taking the preset coordinate diagram of the middle of the wafer as needed as shown in FIG. 4, 2×2 module, the interval is 3×3, and the combined test schematic diagram is shown in FIG. 5.

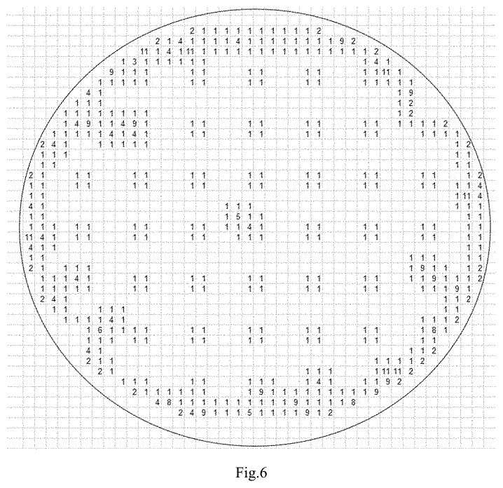

FIG. 6 is a test graphic of an actual wafer after the algorithm is adopted by the present invention. The number represents the test result of the die. Under normal circumstances, “1” indicates that the die is qualified, and all other data are failed.

A single test time is 4.56 s, a single wafer has a total of 1220 die, a lot has a total of 25 wafers, the test efficiency statistics are shown in Table 1:

TABLE 1

| | | Number of | Adjusted | Reduced | |
|---|---|---|---|---|---|
| | Number | original | test | the number | Saved |
| Wafer ID | of die | tests | quantity | of tests | time(s) |
| DET838_01 | 1220 | 1220 | 479 | 741 | 3378.96 |
| DET838_02 | 1220 | 1220 | 464 | 756 | 3447.36 |
| DET838_03 | 1220 | 1220 | 530 | 690 | 3146.4 |
| DET838_04 | 1220 | 1220 | 445 | 775 | 3534 |
| DET838_05 | 1220 | 1220 | 446 | 774 | 3529.44 |
| DET838_06 | 1220 | 1220 | 530 | 690 | 3146.4 |
| DET838_07 | 1220 | 1220 | 479 | 741 | 3378.96 |
| DET838_08 | 1220 | 1220 | 480 | 740 | 3374.4 |
| DET838_09 | 1220 | 1220 | 455 | 765 | 3488.4 |
| DET838_10 | 1220 | 1220 | 476 | 744 | 3392.64 |
| DET838_11 | 1220 | 1220 | 523 | 697 | 3178.32 |
| DET838_12 | 1220 | 1220 | 474 | 746 | 3401.76 |
| DET838_13 | 1220 | 1220 | 472 | 748 | 3410.88 |
| DET838_14 | 1220 | 1220 | 453 | 767 | 3497.52 |
| DET838_15 | 1220 | 1220 | 442 | 778 | 3547.68 |
| DET838_16 | 1220 | 1220 | 442 | 778 | 3547.68 |
| DET838_17 | 1220 | 1220 | 446 | 774 | 3529.44 |
| DET838_18 | 1220 | 1220 | 431 | 789 | 3597.84 |
| DET838_19 | 1220 | 1220 | 463 | 757 | 3451.92 |
| DET838_20 | 1220 | 1220 | 442 | 778 | 3547.68 |
| DET838_21 | 1220 | 1220 | 505 | 715 | 3260.4 |
| DET838_22 | 1220 | 1220 | 431 | 789 | 3597.84 |
| DET838_23 | 1220 | 1220 | 521 | 699 | 3187.44 |
| DET838_24 | 1220 | 1220 | 455 | 765 | 3488.4 |
| DET838_25 | 1220 | 1220 | 482 | 738 | 3365.28 |
| Total | 30500 | 30500 | 11766 | 18734 | 85427.04 |
| | | | | | (s) |
| | | | | | 23.729733 |
| | | | | | (h) |

The algorithm of test graphics can not only consider the reduction of test time, but should comprehensively consider the coverage of failed chips, so the complete test of this batch, the statistical results are shown in Table 2:

TABLE 2

| | Number | | | Adjusted | Adjusted | Adjusted | FAIL | | FAIL |
|---|---|---|---|---|---|---|---|---|---|
| | of | Original | Original | test | test | test | Miss | Original | Miss |
| Wafer ID | die | PASS | FAIL | quantity | PASS | FAIL | Die | Yield | Yield |
| DET838_20 | 1220 | 1137 | 83 | 442 | 383 | 59 | 24 | 93% | 29% |
| DET838_18 | 1220 | 1134 | 86 | 431 | 372 | 59 | 27 | 93% | 31% |
| DET838_16 | 1220 | 1131 | 89 | 442 | 381 | 61 | 28 | 93% | 31% |
| DET838_22 | 1220 | 1131 | 89 | 431 | 374 | 57 | 32 | 93% | 36% |
| DET838_08 | 1220 | 1130 | 90 | 480 | 414 | 66 | 24 | 93% | 27% |
| DET838_24 | 1220 | 1130 | 90 | 455 | 391 | 64 | 26 | 93% | 29% |
| DET838_13 | 1220 | 1129 | 91 | 472 | 407 | 65 | 26 | 93% | 29% |
| DET838_14 | 1220 | 1127 | 93 | 453 | 383 | 70 | 23 | 92% | 25% |
| DET838_25 | 1220 | 1126 | 94 | 482 | 409 | 73 | 21 | 92% | 22% |
| DET838_15 | 1220 | 1118 | 102 | 442 | 384 | 58 | 44 | 92% | 43% |
| DET838_19 | 1220 | 1116 | 104 | 463 | 397 | 66 | 38 | 91% | 37% |
| DET838_10 | 1220 | 1112 | 108 | 476 | 410 | 66 | 42 | 91% | 39% |
| DET838_05 | 1220 | 1111 | 109 | 446 | 382 | 64 | 45 | 91% | 41% |
| DET838_09 | 1220 | 1110 | 110 | 455 | 393 | 62 | 48 | 91% | 44% |
| DET838_02 | 1220 | 1109 | 111 | 464 | 387 | 77 | 34 | 91% | 31% |
| DET838_12 | 1220 | 1108 | 112 | 474 | 400 | 74 | 38 | 91% | 34% |
| DET838_04 | 1220 | 1104 | 116 | 445 | 385 | 60 | 56 | 90% | 48% |
| DET838_21 | 1220 | 1099 | 121 | 505 | 423 | 82 | 39 | 90% | 32% |
| DET838_07 | 1220 | 1098 | 122 | 479 | 403 | 76 | 46 | 90% | 38% |
| DET838_17 | 1220 | 1097 | 123 | 446 | 387 | 59 | 64 | 90% | 52% |
| DET838_03 | 1220 | 1090 | 130 | 530 | 444 | 86 | 44 | 89% | 34% |
| DET838_11 | 1220 | 1085 | 135 | 523 | 445 | 78 | 57 | 89% | 42% |
| DET838_01 | 1220 | 1084 | 136 | 479 | 401 | 78 | 58 | 89% | 43% |
| DET838_23 | 1220 | 1077 | 143 | 521 | 431 | 90 | 53 | 88% | 37% |
| DET838_06 | 1220 | 1048 | 172 | 530 | 432 | 98 | 74 | 86% | 43% |

From a statistical point of view, the higher the yield, the lower the FAIL Miss yield (test failure rate), which will cause the Fail chip to flow to the next level for packaging fewer, which will not cause the packaging cost to rise.

Secondly, the test graphics can also be changed by appropriately increasing the number of test dies. For example, the previous 2×2 module is spaced at 3×3; when it is modified to 2×2, 1×1, the statistical results are shown in Table 3 and Table 4:

TABLE 3

| | | Number of | Adjusted | Reduced | |
|---|---|---|---|---|---|
| | Number | original | test | the number | Saved |
| Wafer ID | of die | tests | quantity | of tests | time(s) |
| DET838_01 | 1220 | 1220 | 739 | 481 | 2193.36 |
| DET838_02 | 1220 | 1220 | 758 | 462 | 2106.72 |
| DET838_03 | 1220 | 1220 | 745 | 475 | 2166 |
| DET838_04 | 1220 | 1220 | 770 | 450 | 2052 |
| DET838_05 | 1220 | 1220 | 800 | 420 | 1915.2 |
| DET838_06 | 1220 | 1220 | 772 | 448 | 2042.88 |
| DET838_07 | 1220 | 1220 | 790 | 430 | 1960.8 |
| DET838_08 | 1220 | 1220 | 760 | 460 | 2097.6 |
| DET838_09 | 1220 | 1220 | 756 | 464 | 2115.84 |
| DET838_10 | 1220 | 1220 | 799 | 421 | 1919.76 |
| DET838_11 | 1220 | 1220 | 782 | 438 | 1997.28 |
| DET838_12 | 1220 | 1220 | 789 | 431 | 1965.36 |
| DET838_13 | 1220 | 1220 | 821 | 399 | 1819.44 |
| DET838_14 | 1220 | 1220 | 821 | 399 | 1819.44 |
| DET838_15 | 1220 | 1220 | 780 | 440 | 2006.4 |
| DET838_16 | 1220 | 1220 | 813 | 407 | 1855.92 |
| DET838_17 | 1220 | 1220 | 794 | 426 | 1942.56 |
| DET838_18 | 1220 | 1220 | 818 | 402 | 1833.12 |
| DET838_19 | 1220 | 1220 | 790 | 430 | 1960.8 |
| DET838_20 | 1220 | 1220 | 854 | 366 | 1668.96 |
| DET838_21 | 1220 | 1220 | 823 | 397 | 1810.32 |
| DET838_22 | 1220 | 1220 | 875 | 345 | 1573.2 |
| DET838_23 | 1220 | 1220 | 865 | 355 | 1618.8 |
| DET838_24 | 1220 | 1220 | 861 | 359 | 1637.04 |
| DET838_25 | 1220 | 1220 | 923 | 297 | 1354.32 |
| Total | 30500 | 30500 | 20098 | 10402 | 47433.12 |
| | | | | | (s) |
| | | | | | 13.175867 |
| | | | | | (h) |

TABLE 4

| | Number | | | Adjusted | Adjusted | Adjusted | FAIL | | FAIL |
|---|---|---|---|---|---|---|---|---|---|
| | of | Original | Original | test | test | test | Miss | Original | Miss |
| Wafer ID | die | PASS | FAIL | number | PASS | FAIL | Die | Yield | Yield |
| DET838_20 | 1220 | 1137 | 83 | 739 | 673 | 66 | 17 | 93% | 20% |
| DET838_18 | 1220 | 1134 | 86 | 758 | 688 | 70 | 16 | 93% | 19% |
| DET838_16 | 1220 | 1131 | 89 | 745 | 674 | 71 | 18 | 93% | 20% |
| DET838_22 | 1220 | 1131 | 89 | 770 | 694 | 76 | 13 | 93% | 15% |
| DET838_08 | 1220 | 1130 | 90 | 800 | 719 | 81 | 9 | 93% | 10% |
| DET838_24 | 1220 | 1130 | 90 | 772 | 698 | 74 | 16 | 93% | 18% |
| DET838_13 | 1220 | 1129 | 91 | 790 | 711 | 79 | 12 | 93% | 13% |
| DET838_14 | 1220 | 1127 | 93 | 760 | 679 | 81 | 12 | 92% | 13% |
| DET838_25 | 1220 | 1126 | 94 | 756 | 681 | 75 | 19 | 92% | 20% |
| DET838_15 | 1220 | 1118 | 102 | 799 | 717 | 82 | 20 | 92% | 20% |
| DET838_19 | 1220 | 1116 | 104 | 782 | 700 | 82 | 22 | 91% | 21% |
| DET838_10 | 1220 | 1112 | 108 | 789 | 708 | 81 | 27 | 91% | 25% |
| DET838_05 | 1220 | 1111 | 109 | 821 | 729 | 92 | 17 | 91% | 16% |
| DET838_09 | 1220 | 1110 | 110 | 821 | 724 | 97 | 13 | 91% | 12% |
| DET838_02 | 1220 | 1109 | 111 | 780 | 690 | 90 | 21 | 91% | 19% |
| DET838_12 | 1220 | 1108 | 112 | 813 | 718 | 95 | 17 | 91% | 15% |
| DET838_04 | 1220 | 1104 | 116 | 794 | 708 | 86 | 30 | 90% | 26% |
| DET838_21 | 1220 | 1099 | 121 | 818 | 718 | 100 | 21 | 90% | 17% |
| DET838_07 | 1220 | 1098 | 122 | 790 | 699 | 91 | 31 | 90% | 25% |
| DET838_17 | 1220 | 1097 | 123 | 854 | 752 | 102 | 21 | 90% | 17% |
| DET838_03 | 1220 | 1090 | 130 | 823 | 718 | 105 | 25 | 89% | 19% |
| DET838_11 | 1220 | 1085 | 135 | 875 | 759 | 116 | 19 | 89% | 14% |
| DET838_01 | 1220 | 1084 | 136 | 865 | 749 | 116 | 20 | 89% | 15% |
| DET838_23 | 1220 | 1077 | 143 | 861 | 739 | 122 | 21 | 88% | 15% |
| DET838_06 | 1220 | 1048 | 172 | 923 | 777 | 146 | 26 | 86% | 15% |

From the statistical results, increasing the number of tests can significantly improve FAIL Miss yield. According to this, the design test graphics can be adjusted to achieve a reasonable detection accuracy rate, which saves time and guarantees the accuracy rate in the later period.

What is claimed is:

1. An optimization method for an integrated circuit wafer test, wherein it includes the following steps:
1) pre-designing a number of dies and coordinates of a die for a wafer to be tested by means of the size of the wafer, the number of dies and the number of test stations that the probe card can test;
2) storing the coordinates of a die to be tested in a coordinate library to be tested, storing the other coordinates in a coordinate library not to be tested and designing the walking sequence of the wafer test;
3) obtaining the coordinates of a die to be tested from the coordinate library to be tested by a test system, starting the test, controlling the wafer prober to test at a specified coordinates by the control system, by means of the coordinates sent by the test system;
4) the test result is returned to the test system and the test result is judged by the test system:
1) if the test result is qualified, then put the coordinates of the die into a coordinate library that has completed the test;
2) if the test result is failed, then put the coordinates of the die into a coordinate library that has completed the test, the test system generates 8 die coordinates around the center of the coordinates of the die, and compare the 8 generated die coordinates with the coordinate library that has completed the test one by one, if the generated die coordinates already exist in the coordinate library that has completed, then remove the generated die coordinates; if the generated die coordinates not exist in the coordinate library that has completed, then add the generated die coordinates into the coordinate library to be tested;
5) continue to return to step 3) for the next coordinate die test until the coordinate library to be tested is tested;
6) processing all the coordinates testing result in the coordinate library not to be tested as being qualified;
7) merging the coordinate library that has completed the test and the coordinate library not to be tested, if the coordinates exist in the two libraries at the same time, the coordinate library that has completed the test is taken as the final result, and combining coordinate libraries to generate actual test graphics for subsequent processes.

2. The optimization method for an integrated circuit wafer test of claim 1, wherein the specific step of pre-designing the test graphics in step 1) includes the following steps: designing the test graphics by means of the overall chip yield and the test efficiency to be achieved, firstly pre-setting the coordinates, and the edge of the wafer is the area that must be tested, take 1 or 2 die on the edge as a unit, setting one circle of the edge of the wafer as the test coordinate; secondly setting the middle position as required, designing the test position module and spacing value according to the product yield of the product and the required test efficiency, setting the coordinates of the whole wafer according to the test coordinates; finally combine test coordinates as design test graphics.
